(19) United States
(12) Patent Application Publication
(10) Pub. No.: US 2008/0191317 A1
(43) Pub. Date: Aug. 14, 2008

(54) SELF-ALIGNED EPITAXIAL GROWTH OF SEMICONDUCTOR NANOWIRES

(75) Inventors: Guy Moshe Cohen, Mohegan Lake, NY (US); Hariklia Deligianni, Tenafly, NJ (US); Qiang Huang, Ossining, NY (US); Lubomyr T. Romankiw, Briarcliff Manor, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/674,453

(22) Filed: Feb. 13, 2007

(51) Int. Cl. H01L 29/06; H01L 21/20

(52) U.S. Cl. 257/618; 438/503; 257/E29.005; 257/E21.09

(57) ABSTRACT

Disclosed herein is a method of forming a nanostructure having nanowires by forming a mask with at least one opening on a surface of a substrate, to expose a portion of the surface of the substrate; depositing particles of a metal capable of catalyzing semiconductor nanowire growth on the exposed surface of the substrate by electroplating or electroless plating; and growing nanowires on the plated substrate with a precursor gas by a vapor-liquid-solid (VLS) process. Also disclosed is a nanostructure including nanowires prepared by the above method.

### FIELD OF THE INVENTION

The present invention relates to a method for forming self-aligned semiconductor nanowires. More particularly, this invention relates to a method of electrochemically or electrolessly depositing metal nanoparticles at specific locations on a substrate to catalyze formation of epitaxial semiconductor nanowires at these locations by vapor-liquid-solid growth process.

### BACKGROUND OF THE INVENTION

Inorganic nanowires, sometimes referred to as “whiskers”, can be grown on surfaces by a vapor-liquid-solid (VLS) process as described in U.S. Pat. Nos. 3,493,431, 5,702,822, and 5,858,862. As disclosed therein, semiconductor nanowires grown by VLS process, such as Si, Ge, GaAs and InP nanowires, are of particular interest for fabricating integrated electronic devices based on nanowire field effect transistors (FETs). Nanowire FETs can exhibit the advantageous quantum effects and also allow for 3-dimensional device integration, and hence may provide a much higher device density than the current technologies. However, a key challenge for the integration of such nanowires into real device is the difficulty in placing the wires precisely at desired locations.

There is an ongoing effort to understand and improve the growth process of epitaxial semiconductor. Growth of the semiconductor wires by VLS process generally requires catalytic metal particles, such as Au or In particles. The metal particle(s direct the growth of the wires by catalyzing the formation of the nanowires at the interface of the substrate surface and the metal particles. The position of the wires is therefore determined by where the particle is placed. However, the present methods for growth of such nanowires provide non-site specific methods for depositing the catalytic metal particles and growing the nanowires, necessitating the use of methods such as lift-off layers or nanoimprint lithography to pattern the metal particles in order to direct the growth of nanowires.

Accordingly, it is desirable to grow epitaxial nanowires selectively in predetermined locations on a surface of a substrate, using a method that avoids the use of potentially problematic, nonstandard, or highly specialized processing steps.

### SUMMARY OF THE INVENTION

The deficiencies of the prior art can be overcome by a method disclosed herein of forming self-aligned epitaxial semiconductor nanowires on substrates. More specifically, disclosed herein is a method of electrochemically or electrolessly depositing the catalytic nanoparticles in predetermined regions on silicon substrates, and thus growing the semiconductor nanowires.

In an embodiment, a method of forming a nanostructure comprising nanowires, comprises: forming a mask on a surface of a substrate, wherein the mask has at least one opening to expose a portion of the surface of the masked substrate; depositing metal particles of a metal or metal alloy for catalyzing semiconductor nanowire growth on the exposed surface of the masked substrate to form a plated substrate; and growing nanowires on the plated substrate with the location of the nanowires defined by the plated metal particles. In an embodiment, the nanowires are grown by a vapor-liquid-solid (VLS) process with a nanowire precursor gas.

In another embodiment, a method of forming a nanostructure comprises: forming a mask on a surface of a substrate, wherein the mask has at least one opening to expose a portion of the surface of the masked substrate; cleaning the exposed surface of the masked substrate with dilute aqueous hydrofluoric acid solution; plating metal particles of a metal for catalyzing semiconductor nanowire growth on the exposed surface of the masked substrate to form a plated substrate by immersing the masked substrate and an anode into a plating solution containing a metal particle precursor for the metal particles, and applying an electrical plating current for a predetermined time across the masked substrate and anode, wherein the metal particle precursor is gold, indium, or alloys thereof, the plating current is −1 mA/cm² to −100 mA/cm², the plating time is less than or equal to 10 seconds, and light illumination is optionally applied to the masked substrate, wherein the size and the density of the metal particles are tuned by changing plating conditions comprising plating current, plating potential, plating time, agitation, temperature, illumination of the substrate, concentration of the metal species in the plating solution, addition of other chemical species to the plating solution, concentration of other chemical species in the plating solution, or a combination comprising at least one of these plating conditions; cleaning the plated substrate with dilute aqueous hydrofluoric acid solution; annealing the plated substrate prior to growing nanowires, wherein annealing is carried out at 300 to 550° C. for 10 minutes to 2 hours in an inert or reducing atmosphere, cleaning the plated substrate after annealing, with dilute aqueous hydrofluoric acid solution, and growing nanowires on the plated substrate with a nanowire precursor gas by a vapor-liquid-solid (VLS) process.

In another embodiment, a method of forming a nanostructure comprises: forming a mask on a surface of a substrate, wherein the mask has at least one opening to expose a portion of the surface of the masked substrate; cleaning the exposed surface of the masked substrate with dilute aqueous hydrofluoric acid solution; plating metal particles of a metal for catalyzing semiconductor nanowire growth on the exposed surface of the masked substrate to form a plated substrate by immersing the masked substrate into a plating solution containing a metal particle precursor for the metal particles, and a reducing agent, wherein plating is carried out at 10° C. to 90° C., with or without agitation, and the plating time is 1 second to 30 minutes, wherein the size and density of the metal particles are tuned by changing plating conditions comprising immersion time, agitation, temperature, illumination, concentration of the metal particle precursor, identity and concentration of the reducing agents in the plating solution, addition of other chemical species in the plating solution, concentration of other chemical species in the plating solution, or a combination comprising at least one of these plating conditions; cleaning the plated substrate with dilute aqueous hydrofluoric acid solution; annealing the plated substrate prior to growing nanowires, wherein annealing is carried out at 300 to 550° C. for 10 minutes to 2 hours in an inert or reducing atmosphere, cleaning the plated substrate after annealing, with dilute aqueous hydrofluoric acid solution, and growing nanowires on the plated substrate with a nanowire precursor gas by a vapor-liquid-solid (VLS) process with the location of the nanowires defined by the plated metal particles.

In another embodiment, a nanostructure prepared by an above-described method is disclosed. Also in an embodiment, the nanowires grow on the exposed region on the substrate and are epitaxial to the substrate. The silicon nanowires are from 1 to 100 nm in diameter. The length of the wires can be 0.1 μm to 100 μm depending on the growth time.

Still other advantages of the present invention will become readily apparent by those skilled in the art from the following detailed description, wherein it is shown and described in the preferred embodiments, by way of illustration of the best mode. As will be realized, the disclosure is capable of other and different embodiments, and its several details are capable of modifications without departing from the spirit of the disclosure. Accordingly, the description is to be regarded as illustrative in nature and not as restricted thereto.

### BRIEF DESCRIPTION OF THE DRAWINGS

FIG. 1 is a schematic diagram of an exemplary process for growing self-aligned epitaxial semiconductor nanowires from a patterned substrate; and

FIG. 2 is a micrograph from a scanning electron microscope (SEM) of exemplary self-aligned epitaxial silicon nanowires formed according to the method of the present invention.

### DETAILED DESCRIPTION OF THE INVENTION

A method of producing self-aligned epitaxial semiconductor nanowires on substrates is disclosed. The method includes plating (i.e., depositing) metal particles on a patterned substrate having cleaned, exposed regions; annealing the plated metal particles on the substrate; and growing nanowires from the plated metal particles by a VLS process at a predetermined temperature in an apparatus having a chamber, with a nanowire precursor gas (e.g., silane SiH₄ for silicon nanowires; germane GeH₄ for germanium nanowires; and the like). The diameter of the nanowire prepared by this method is proportional to the size (i.e., diameter) of the metal particle, specifically to the diameter of the hemispherical metal particle as measured at the interface of the metal particle and the substrate. The method selectively provides metal particles for catalyzing growth of nanowires on the surface of the substrate to thereby provide patterns of metal particles on the surface of the substrate, using readily available methods and without need for potentially problematic or nonstandard patterning methods such as use of lift-off layers (LOL) or nanoimprint lithography.

In one embodiment of the present invention, the metal particles are deposited by immersing the substrate into a electroplating solution containing one or more precursor metal species for a metal or metal alloy particle (e.g., gold, indium, alloys thereof, or the like, with an average particle size, i.e., the average diameter of the particles, of 1 to 100 nm but not limited thereto); electroplating the metal from the electrolyte solution selectively onto the substrate to form metal particles in the exposed regions. Exemplary plating solutions are described in U.S. Pat. Nos. 4,077,852, 4,744,871, 4,755,264. The size and the density of the metal particles can be tuned by changing the plating conditions including plating current, plating potential, plating time, agitation, temperature, illumination of the substrate, concentration of the metal species in the plating solution, addition of other chemical species to the plating solution, concentration of other chemical species in the plating solution, or a combination comprising at least one of the foregoing plating conditions.

In another embodiment of the present invention, the metal particles are deposited by immersing the substrate into a electroless plating solution containing one or more precursor metal species for a metal or metal alloy particle (e.g., gold, indium, alloys thereof, or the like, with an average particle size of 1 to 100 nm, but not limited thereto) and at least one reducing agent. Metal particles are formed selectively onto the substrate in the exposed regions. Exemplary electroless plating solutions are described in U.S. Pat. Nos. 4,804,559, 5,160,373, 5,198,273, 5,935,306 and 6,855,191. The size and density of the metal particles can be tuned by changing plating conditions comprising the immersion time, agitation, temperature, illumination, concentration of the metal particle precursor, identity and concentration of the reducing agents in the plating solution, addition of other chemical species in the plating solution, concentration of other chemical species in the plating solution, or a combination comprising at least one of these plating conditions.

The nanowires as described herein are formed of one or more semiconducting materials that are of the same or different composition as that of the composition of the substrate. In an embodiment, the nanowire has a diameter of less than or equal to 100 nm, specifically less than or equal to 50 nm, and more specifically less than or equal to 20 nm. In an embodiment, the nanowire has a diameter of greater than or equal to 1 nm, specifically greater than or equal to 3 nm, and more specifically greater than or equal to 5 nm. Also in an embodiment, the nanowire has a length of 0.1 μm to 100 μm, and specifically 1 μm to 10 μm.

The nanowires are included as a portion of a nanostructure, where the nanostructure is formed on an exposed surface of the substrate through a mask formed on the surface of the substrate. The mask is patterned to have one or more openings, which define the locations of the nanostructure, and which expose the underlying surface of the substrate. The opening in the mask is not limited as to size or shape, and can be regular or irregular, symmetric or asymmetric, simple in structure such as exemplified by a contact hole or trench, or complex in structure as for example where more than one such contact hole or trench is present in the nanostructure. In an embodiment, the nanostructure is not limited in size and can have a largest dimension of 0.1 μm to 100 μm.

One or more whisker structures (i.e., nanowires) are included on the substrate exposed through the openings in the mask, where the nanowires so formed using the above method are in contact with and epitaxial to the substrate.

Thus, in an embodiment, a method of forming a nanostructure comprising nanowires includes forming a mask on a surface of a substrate, wherein the mask has at least one opening to expose the surface of the substrate; plating metal or metal alloy particles on the exposed surface of the substrate to form a plated substrate by immersing the masked substrate and an anode into a plating solution containing a metal precursor for the metal particles, and applying an electrical potential across the masked substrate and anode; and growing nanowires on the plated substrate by a VLS semiconductor whisker growth method.

The method is further illustrated in the figures, and a description of the exemplary embodiments is provided herein.

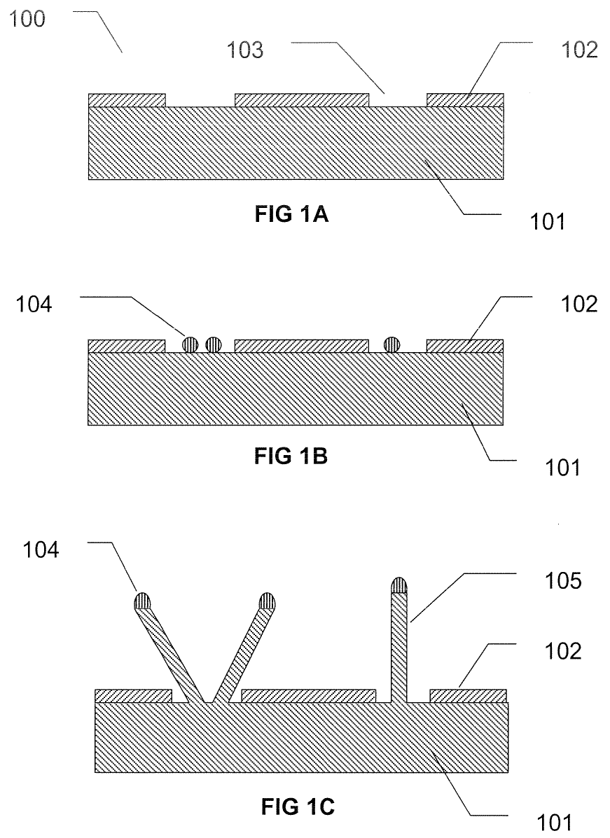

FIGS. 1A to 1C illustrate a method used to grow the self-aligned semiconductor nanowires in this invention. FIG. 1A is the schematic diagram of a patterned substrate 100 on which the semiconducting nanowires are to be formed. The patterned substrate 100 can be prepared by depositing a dielectric layer 102 on a surface of a substrate 101, and patterning the dielectric layer 102 to form open regions 103.

Useful materials for the substrate 101 include but are not limited to: Si-based or Ge-based semiconductors such as Si, Ge, or SiGe alloys; group III-V semiconductors such as GaAs or InP; and group II-VI semiconductors such as ZnO, ZnS or CdS; or a combination comprising at least one of the foregoing semiconductors. The substrate can also comprise a conductive material including but not limited to NiSi, PtSi and FeSi. The substrate can include one or more layers, including a combination of dielectric, conducting, and semiconducting layers, such as, in an embodiment, silicon-on-insulator (SOI) or like multilayer substrates. In a specific embodiment, the substrate is a semiconducting substrate.

Useful dielectric materials for layer 102 include but are not limited to: SiO₂, Si₃N₄, SiON, Al₂O₃, SiCO, fluorinated silica glass (FSG), organic silicate glass (OSG), spin-on glass (SOG), or the like, or a combination comprising at least one of the foregoing dielectric materials. Where a combination of dielectric materials is used, the materials are desirably deposited in sequential layers, where any number of layers may be used. Also, where a combination of dielectric materials is deposited in sequential layers, no particular order to the layers is required by the method, but it is contemplated that suitable combinations of dielectric materials within the scope of the present invention will become apparent to one skilled in the art in the practice of the invention as disclosed herein.

Patterning processes can be used after deposition of the dielectric layer 102 to create open regions 103 in the dielectric layer 102, where the surface of the substrate 101 is partially exposed through the open regions 103. Useful patterning processes for forming the patterns (i.e., open regions 103) in the dielectric layer 102 include but are not limited to standard photolithography methods including for example those carried out at UV wavelengths including g-Line (436 nm), i-Line (365 nm), DUV 248 nm, and 193 nm wavelengths, electron beam lithography, x-ray lithography, self alignment of diblock copolymers, reactive ion etch, or a combination comprising at least one of the foregoing processes.

FIG. 1B is a schematic diagram showing the nanoparticles 103 plated in the exposed (i.e., patterned) region on the substrate 100, according to one embodiment of the present invention. The substrate 100 is cleaned in a dilute HF solution and rinsed with water before plating. A typical cleaning is performed in a dilute (e.g., 1 part HF to 100 parts water, i.e., 1:100) aqueous hydrofluoric acid (HF) solution for 5 seconds to 5 minutes, depending on the nature of the substrate and the thickness and nature of the patterned dielectric layer. The composition and thickness of the dielectric layer are chosen such that it withstands the HF cleaning processes and the immersion in the subsequent plating solution. The plating can be carried out in a solution containing metals such as gold, indium, or other metal species that can catalyze the semiconductor nanowire growth. The plating solution can optionally include other chemical species that change the size and density of the plated metal particles. Chemical species for changing size and density of the metal particles include, but are not limited to, inorganic species such as Tl, Sb, As, I; chelating agents such as citrate, tartrate, ethylenediaminetetraacetic acid (EDTA); organic additives such as thiourea; and other inhibitors, accelerators, and levelers. The plating can be carried out with or without agitation. The plating current is typically −1 mA/cm² to −100 mA/cm², and the plating time is typically less than or equal to 10 seconds depending on the plating solution, plating conditions, and the desired particle size. The plating can be carried out at any temperature where solution is stable, typically at 5° C. to 90° C., and more typically 20° C. to 60° C. The plating can be carried out with or without illumination depending on the nature of the substrate 101.

In another embodiment, the nanoparticles 103 are deposited by immersing the substrate 100 into an electroless plating solution. The substrate 100 is cleaned in a dilute HF solution and rinsed with water before plating. The plating solution contains one or more reducing agents and metal species such as gold, indium, or other metal species that can catalyze the semiconductor nanowire growth. The plating solution can optionally contain other chemical species that changes the size and density of the plated metal particles. Typical chemical species includes but not limited to inorganic species such as Tl, Sb, As, I; chelating agents such as citrate, tartrate, ethylenediaminetetraacetic acid (EDTA); organic additives such as thiourea; and other inhibitors, accelerators and levelers. The plating can be carried out at 10° C. to 90° C., and more specifically 30° C. to 90° C. The plating can be carried out with or without agitation. The plating time can be 1 second to 30 minutes depending on the plating solution, plating conditions and the desired particle size.

FIG. 1C is the schematic diagram showing the semiconductor nanowires grown in the open area 103 from the plated catalyst particles 104. Catalyst particles 104, which melt at the high temperature used during the nanowire growth step, flatten at the point of contact with the surface and as such are typically roughly hemispherical in shape. After the plating of catalyst particles 104, the substrate 100 is cleaned in a dilute aqueous HF solution, typically in a 1:100 aqueous HF solution, for typically about 2 minutes. Immediately after the cleaning, an annealing process is carried out in an inert or reducing environment, such as for example in the presence of a gas including nitrogen, helium, argon, forming gas (e.g., a combination of up to 10 vol % hydrogen in nitrogen), or other inert or reducing environment. A typical condition for annealing is 300 to 550° C. for about 10 minutes to about 2 hours. The substrate 100 is then cleaned in dilute aqueous HF and transferred into a vacuum chamber for nanowire growth. The growth of the nanowires can be carried out according to a known method. The point of growth of the nanowires 105 is at the interface of the flattened portion of the catalyst particles 104, initially with the underlying surface of substrate 101 exposed in open area 103, and subsequently with the portion of the nanowires 105 in contact with the catalyst particle 104 where the nanowire growth occurs. The semiconductor nanowires 105 that can be grown include but are not limited to those formed of semiconductors including: Si, Ge, SiGe, SiC, group III-V semiconductors such as InP, group II-VI semiconductors such as ZnO, or a combination comprising at least one of the foregoing semiconductors.

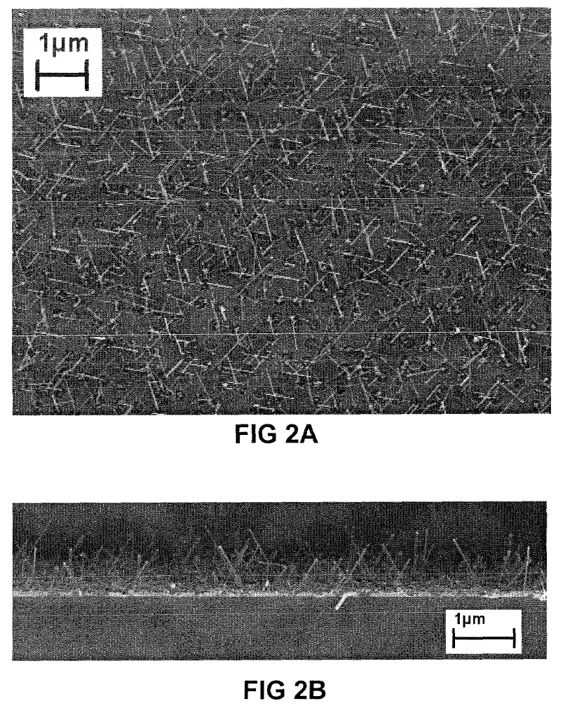

An exemplary process for making nanowires is as follows. FIGS. 2A and 2B are top view and cross section view electron micrographs, respectively, of silicon nanowires grown from plated gold particles. The exemplary substrate shown is single crystal (111) p-type silicon covered with a dielectric stack composed of 10 nm SiO₂ and 20 nm Si₃N₄. Vias of 200 nm diameter were formed by UV lithography and reactive ion etching. Before the gold plating, the substrate was cleaned in 1:100 aqueous HF solution for 2 minutes.

The patterned substrate is mounted on to plating apparatus with the electrical contact made through the backside of the substrate. The gold nanoparticles were electroplated in a gold solution containing about 5 mM Au at a current density of about −50 mA/cm² for about 1.5 seconds. The substrate was under illumination during the electroplating. The substrate with the plated gold was then cleaned in 1:100 aqueous HF solution for about 1 minute, annealed in forming gas at about 400° C. for about 1 hour, cleaned again in 1:25 aqueous HF solution for about 30 seconds, and then loaded into a growth chamber for silicon nanowire growth. The wires shown in FIGS. 2A and 2B were grown at about 450° C. for about 8 minutes with silane as the precursor.

The top view image in FIG. 2A shows that most of the wires are epitaxial to the (111) silicon substrate as they grow in three directions 120° to each other. The cross sectional image in FIG. 2B shows that most of the wires grow either perpendicular to the substrate or in a direction of about 54° to the substrate surface, and are (111) and (110) wires, respectively. The (110) wires correspond to the wires in three directions on the top view image in FIG. 2A and the (111) wires could not be observed on top view image as their projection is obscured from this view by the corresponding metal particle.

The foregoing description illustrates and describes the present disclosure. Additionally, the disclosure shows and describes only the preferred embodiments of the disclosure, but, as mentioned above, it is to be understood that the invention is capable of changes or modifications within the scope of the concept as expressed herein, commensurate with the above teachings and/or skill or knowledge of the relevant art and without departing from the spirit of the invention. For instance, the features or steps can be performed in a differing order, or the features or steps can be added, deleted or modified. All of these variations are considered a part of the claimed invention. The embodiments described hereinabove are further intended to explain best modes known of practicing the invention and to enable others skilled in the art to utilize the disclosure in such, or other, embodiments and with the various modifications required by the particular applications or used disclosed herein. Accordingly, the description is not intended to limit the invention to the form disclosed herein.

All publications, patents and patent applications cited in this specification are herein incorporated by reference, and for any and all purposed, as if each individual publication, patent or patent application were specifically and individually indicates to be incorporated by reference. In the case of inconsistencies, the present disclosure will prevail.

The term “comprising” (and its grammatical variations) as used herein is used in the inclusive sense of “having” or “including” and not in the exclusive sense of “consisting only of”. The singular forms “a,” “an,” and “the” include plural referents unless the context clearly dictates otherwise. The endpoints of all ranges reciting the same characteristic or component are independently combinable and inclusive of the recited endpoint. All references are incorporated herein by reference. The terms “first,” “second,” and the like herein do not denote any order, quantity, or importance, but rather are used to distinguish one element from another. As used herein and unless otherwise specified, a feature that “forms on”, “is formed on”, and “is forming on” another feature, including where other similar variants of the term “form” is used, mean that the feature so formed is in at least partial contact with the other feature.

While the preferred embodiment to the invention has been described, it will be understood that those skilled in the art, both now and in the future, may make various improvements and enhancements which fall within the scope of the claims which follow.

What is claimed as new and desired to be protected by Letters Patent of the United States is:

1. A method of forming a nanostructure comprising nanowires, comprising:
forming a mask on a surface of a substrate, wherein the mask has at least one opening to expose a portion of the surface of the masked substrate;
depositing metal particles of a metal or metal alloy for catalyzing semiconductor nanowire growth on the exposed surface of the masked substrate to form a plated substrate;
growing nanowires on the plated substrate with the location of the nanowires defined by the plated metal particles.

2. The method of claim 1, wherein forming the mask is done by patterning the substrate by standard photolithography, electron beam lithography, x-ray lithography, self-alignment of diblock copolymer, reactive ion etch, or a combination comprising at least one of the foregoing processes.

3. The method of claim 1, wherein the metal particles comprise gold, indium, or alloys thereof, and wherein the metal particles catalyze the growth of nanowire.

4. The method of claim 1 wherein the metal particles are deposited by immersing the masked substrate and an anode into a plating solution containing at least one metal precursor for the metal particles, and applying an electrical plating current for a predetermined plating time across the masked substrate and anode.

5. The method of claim 4, wherein the size and the density of the metal particles are tuned by changing plating conditions including plating current, plating potential, plating time, agitation, temperature, illumination of the substrate, concentration of the metal species in the plating solution, addition of other chemical species to the plating solution, concentration of other chemical species in the plating solution, or a combination comprising at least one of these plating conditions.

6. The method of claim 4, wherein the plating current is −1 mA/cm² to −100 mA/cm², and the plating time is less than or equal to 10 seconds.

7. The method in claim 1 wherein the metal particles are deposited by immersing the masked substrate for a predetermined time into a plating solution containing at least one metal particle precursor and at least one reducing agent.

8. The method of claim 7, wherein the size and density of the metal particles are tuned by changing plating conditions comprising the immersion time, agitation, temperature, illumination, concentration of the metal particle precursor, identity and concentration of the reducing agents in the plating solution, addition of other chemical species in the plating solution, concentration of other chemical species in the plating solution, or a combination comprising at least one of these plating conditions.

9. The method of claim 7, wherein plating can be carried out at 10° C. to 90° C., with or without agitation, and the plating time is 1 second to 30 minutes.

10. The method of claim 1, further comprising annealing the plated substrate prior to growing nanowires.

11. The method of claim 10 wherein annealing is carried out at 300 to 550° C. for 10 minutes to 2 hours in an inert or reducing atmosphere.

12. The method of claim 11, wherein the reducing atmosphere is nitrogen, helium, argon, forming gas, or a combination comprising the foregoing gases.

13. The method of claim 11 where the annealing of the plated substrate is carried out at about 400° C. for about 1 hour in forming gas.

14. The method of claim 1, wherein the nanowires are grown by a vapor-liquid-solid (VLS) process with a nanowire precursor gas.

15. The method of claim 14 wherein the nanowire precursor gas is silane, growing is done at about 450° C. for about 8 minutes, and the resulting nanowires are silicon nanowires.

16. The method of claim 1, further comprising cleaning the exposed surface of the masked substrate prior to plating of the metal particles, cleaning the plated substrate prior to annealing the plated substrate, and cleaning the plated substrate after annealing and prior to growing the nanowires, wherein cleaning is carried out in dilute aqueous hydrofluoric acid solution.

17. A nanostructure prepared by the method of claim 1.

18. The nanostructure in claim 17 wherein the nanowire has a diameter of 1 to 100 nm, and a length of 0.1 μm to 100 μm.

19. A method of forming a nanostructure, comprising:
forming a mask on a surface of a substrate, wherein the mask has at least one opening to expose a portion of the surface of the masked substrate;
cleaning the exposed surface of the masked substrate with dilute aqueous hydrofluoric acid solution;
plating metal particles of a metal for catalyzing semiconductor nanowire growth on the exposed surface of the masked substrate to form a plated substrate by
immersing the masked substrate and an anode into a plating solution containing a metal particle precursor for the metal particles, wherein the metal particle precursor is gold, indium, or alloys thereof, and
applying an electrical plating current for a predetermined time across the masked substrate and anode, wherein the plating current is −1 mA/cm² to −100 mA/cm², the plating time is less than or equal to 10 seconds, and light illumination is optionally applied to the masked substrate, wherein the size and the density of the metal particles are tuned by changing plating conditions comprising plating current, plating potential, plating time, agitation, temperature, illumination of the substrate, concentration of the metal species in the plating solution, addition of other chemical species to the plating solution, concentration of other chemical species in the plating solution, or a combination comprising at least one of these plating conditions;
cleaning the plated substrate with dilute aqueous hydrofluoric acid solution;
annealing the plated substrate prior to growing nanowires, wherein annealing is carried out at 300 to 550° C. for 10 minutes to 2 hours in an inert or reducing atmosphere,
cleaning the plated substrate after annealing, with dilute aqueous hydrofluoric acid solution, and
growing nanowires on the plated substrate with a nanowire precursor gas by a vapor-liquid-solid (VLS) process.

20. A method of forming a nanostructure, comprising:
forming a mask on a surface of a substrate, wherein the mask has at least one opening to expose a portion of the surface of the masked substrate;
cleaning the exposed surface of the masked substrate with dilute aqueous hydrofluoric acid solution;
plating metal particles of a metal for catalyzing semiconductor nanowire growth on the exposed surface of the masked substrate to form a plated substrate by
immersing the masked substrate and an anode into a plating solution containing a metal particle precursor for the metal particles, and a reducing agent, wherein the metal particle precursor is gold, indium, or alloys thereof,
wherein plating is carried out at 10° C. to 90° C., with or without agitation, and the plating time is 1 second to 30 minutes,
wherein the size and density of the metal particles are tuned by changing plating conditions comprising immersion time, agitation, temperature, illumination, concentration of the metal particle precursor, identity and concentration of the reducing agents in the plating solution, addition of other chemical species in the plating solution, concentration of other chemical species in the plating solution, or a combination comprising at least one of these plating conditions;
cleaning the plated substrate with dilute aqueous hydrofluoric acid solution;
annealing the plated substrate prior to growing nanowires, wherein annealing is carried out at 300 to 550° C. for 10 minutes to 2 hours in an inert or reducing atmosphere,
cleaning the plated substrate after annealing, with dilute aqueous hydrofluoric acid solution, and
growing nanowires on the plated substrate with a nanowire precursor gas by a vapor-liquid-solid (VLS) process with the location of the nanowires defined by the plated metal particles.
